(19) United States
(12) Patent Application Publication
(10) Pub. No.: US 2013/0045599 A1
(43) Pub. Date: Feb. 21, 2013

(54) Method for chemical mechanical polishing copper

(71) Applicant: Qianqiu Ye, Newark, DE (US)

(72) Inventor: Qianqiu Ye, Newark, DE (US)

(73) Assignee: Rohm and Electronic Materials CMP Holdings, Inc., Newark, DE (US)

(21) Appl. No.: 13/209,864

(22) Filed: Aug. 15, 2011

(51) Int. Cl. H01L 21/306; H01L 21/304

(52) U.S. Cl. 438/693; 257/E21.23

(57) ABSTRACT

A method for chemical mechanical polishing of a copper substrate, is provided, comprising: providing a copper substrate; providing slurry composition comprising, as initial components: water; 0.1 to 20 wt % abrasive; 0.01 to 15 wt % complexing agent; 0.02 to 5 wt % inhibitor; 0.01 to 5 wt % phosphorus containing compound; 0.001 to 3 wt % polyvinyl pyrrolidone; >0.1 to 1 wt % histidine; >0.1 to 1 wt % guanidine; optional oxidizing agent; optional leveling agent; optional biocide; and, optional pH adjusting agent; wherein the slurry composition provided has pH of 9 to 11; providing a chemical mechanical polishing pad with a polishing surface; dispensing the slimy composition onto the polishing surface at or near the interface between the polishing surface and the substrate; and, creating dynamic contact at an interface between the polishing surface and the substrate with a down force of 0.69 to 34.5 kPa; wherein the substrate is polished.

The present invention relates to a method for chemical mechanical polishing of a substrate. More particularly, the present invention relates to a method for chemical mechanical polishing of a semiconductor substrate having copper interconnects.

Copper is presently the interconnect material of choice for use in semiconductor wafer integration schemes due to its relatively low resistivity and improved resistance to electro-migration. Given the difficulty associated with etching of copper using plasma, damascene techniques are typically used to produce copper interconnects. In a typical damascene structure, a trench or via is etched into a dielectric layer; a barrier material (typically Ta, TaN) and a seed copper material are then deposited into the trench or via; and then bulk copper is deposited by electroplating. The deposited copper fills the desired area (i.e., the trench or via) and spreads out over the surrounding areas of the wafer. Chemical mechanical polishing (CMP) is then used to remove the unwanted (overburden) copper material and to planarize the wafer surface.

Conventional copper CMP is typically a multi-step process. The typical first step is to use a polishing composition exhibiting a high removal rate selectivity for copper relative to the barrier material to facilitate rapid removal of the bulk of the unwanted (overburden) copper from the wafer surface. The high selectivity polishing composition is designed to facilitate a polish stop on the barrier layer. Notwithstanding, the high copper selectivity first polish step can result in the copper layer disposed inside the trenches or vias becoming polished causing an effect know as dishing. A typical second step is to use another polishing composition (a barrier formulation) to facilitate removal of the barrier material from the waver surface. In a typical low selectivity slurry (LSS) integration scheme, the selected barrier formulation is designed to exhibit a non-selectivity for copper relative to the barrier material to improve the process margins and to reduce dishing. Periodically a third step is implemented (e.g., a buff step) to improve the defectivity of the polished surface.

Improving the defectivity performance in the chemical mechanical polishing of copper is a difficult challenge given the relative softness of copper. The defectivity associated with copper CMP is primarily of the scratch and chatter mark variety. Improving the defectivity in copper CMP is of particular interest because of the associated yield loses and reliability concerns.

One asserted solution for improving defectivity in copper CMP is disclosed by Siddiqui, et al. in U.S. Patent Application Publication No. 2008/0148652. Siddiqui, et al. disclose a composition and associated method for chemical mechanical polishing of a copper containing substrate that is asserted to afford low defectivity levels on copper during copper CMP processing, wherein the composition comprises a colloidal silica that is substantially free of soluble polymeric silicates.

Notwithstanding, there remains an ongoing need for the development of new chemical mechanical polishing compositions and methods that afford improved copper defectivity performance.

The present invention provides a method for chemical mechanical polishing of a substrate, comprising: providing a substrate, wherein the substrate comprises copper; providing a chemical mechanical polishing slurry composition comprising, as initial components: water; 0.1 to 20 wt % of an abrasive; 0.01 to 15 wt % of a complexing agent; 0.02 to 5 wt % of an inhibitor; 0.01 to 5 wt % of a phosphorus containing compound; 0.001 to 3 wt % of a polyvinyl pyrrolidone; >0.1 to 1 wt % histidine; >0.1 to 1 wt % guanidine, wherein the guanidine is selected from guanidine, guanidine derivatives, guanidine salts and mixtures thereof; 0 to 25 wt % of an optional oxidizing agent; 0 to 0.1 wt % of an optional leveling agent; 0 to 0.01 wt % of an optional biocide; an optional pH adjusting agent; wherein the chemical mechanical polishing slurry composition provided has a pH of 9 to 11; providing a chemical mechanical polishing pad with a polishing surface; dispensing the chemical mechanical polishing slurry composition onto the chemical mechanical polishing pad at or near the interface between the chemical mechanical polishing pad and the substrate; and, creating dynamic contact at an interface between the polishing surface of the chemical mechanical polishing pad and the substrate with a down force of 0.69 to 34.5 kPa; wherein the substrate is polished; and, wherein some of the copper is removed from the substrate.

The present invention also provides a method for chemical mechanical polishing of a substrate, comprising: providing a substrate, wherein the substrate comprises copper; providing a chemical mechanical polishing slurry composition comprising, as initial components: water; 0.5 to 15 wt % of an abrasive, wherein the abrasive is a colloidal silica abrasive having an average particle size of 25 to 75 nm; 0.1 to 1 wt % of a complexing agent, wherein the complexing agent is citric acid; 0.05 to 2 wt % of an inhibitor, wherein the inhibitor is benzotriazole; 0.05 to 3 wt % of a phosphorus containing compound, wherein the phosphorus containing compound is phosphoric acid; 0.05 to 1.5 wt % of a polyvinyl pyrrolidone, wherein the polyvinyl pyrrolidone has a weight average molecular weight of 2,500 to 50,000; 0.25 to 1 wt % histidine; 0.25 to 1 wt % guanidine, wherein the guanidine is selected from guanidine, guanidine derivatives, guanidine salts and mixtures thereof; 0.1 to 10 wt % of an oxidizing agent, wherein the oxidizing agent is H₂O₂; 0.01 to 0.1 wt % of a leveling agent, wherein the leveling agent is ammonium chloride; 0.001 to 0.01 wt % of a biocide; and, 0.1 to 1 wt % of a pH adjusting agent, wherein the pH adjusting agent is potassium hydroxide; providing a chemical mechanical polishing pad with a polishing surface; dispensing the chemical mechanical polishing slurry composition onto the chemical mechanical polishing pad at or near the interface between the chemical mechanical polishing pad and the substrate; and, creating dynamic contact at an interface between the polishing surface of the chemical mechanical polishing pad and the substrate with a down force of 0.69 to 34.5 kPa; wherein the substrate is polished; wherein some of the copper is removed from the substrate; and, wherein the chemical mechanical polishing composition facilitates a copper removal rate of ≧1100 Å/min with a post polish SP1 defect count having a size >0.1 μm of ≦200 with a platen speed of 93 revolutions per minute, a carrier speed of 87 revolutions per minute, a chemical mechanical polishing composition flow rate of 300 ml/min, and a nominal down force of 11.7 kPa on a 200 mm polishing machine using a chemical mechanical polishing pad that comprises a polyurethane polishing layer containing polymeric hollow core microparticles and a polyurethane impregnated non-woven subpad.

The present invention also provides a method for chemical mechanical polishing of a substrate, comprising: providing a substrate, wherein the substrate comprises copper; providing a chemical mechanical polishing slurry composition comprising, as initial components: water; 10 to 15 wt % of an abrasive, wherein the abrasive is a colloidal silica abrasive having an average particle size of 25 to 75 nm; 0.01 to 0.5 wt % of the complexing agent, wherein the complexing agent is citric acid; 0.05 to 1 wt % of an inhibitor, wherein the inhibitor is benzotriazole; 0.05 to 0.2 wt % of a phosphorus containing compound, wherein the phosphorus containing compound is phosphoric acid; 0.1 to 1 wt % of a polyvinyl pyrrolidone, wherein the polyvinyl pyrrolidone has a weight average molecular weight of 12,000 to 20,000; 0.25 to 0.6 wt % histidine; 0.25 to 0.6 wt % guanidine HCl; 0.1 to 5 wt % of an oxidizing agent, wherein the oxidizing agent is H₂O₂; 0.01 to 0.05 wt % of a leveling agent, wherein the leveling agent is ammonium chloride; 0.001 to 0.01 wt % of a biocide; and, 0.1 to 1 wt % of a pH adjusting agent, wherein the pH adjusting agent is potassium hydroxide; and, wherein there is ≦10% difference in the mass of histidine and guanidine HCl included as initial components in the chemical mechanical polishing composition; providing a chemical mechanical polishing pad with a polishing surface; dispensing the chemical mechanical polishing slurry composition onto the chemical mechanical polishing pad at or near the interface between the chemical mechanical polishing pad and the substrate; and, creating dynamic contact at an interface between the polishing surface of the chemical mechanical polishing pad and the substrate with a down force of 0.69 to 34.5 kPa; wherein the substrate is polished; wherein some of the copper is removed from the substrate; and, wherein the chemical mechanical polishing composition facilitates a copper removal rate of ≧1100 Å/min with a post polish SP1 defect count having a size >0.1 μm of ≦200 with a platen speed of 93 revolutions per minute, a carrier speed of 87 revolutions per minute, a chemical mechanical polishing composition flow rate of 300 ml/min, and a nominal down force of 11.7 kPa on a 200 mm polishing machine using a chemical mechanical polishing pad that comprises a polyurethane polishing layer containing polymeric hollow core microparticles and a polyurethane impregnated non-woven subpad.

### DETAILED DESCRIPTION

The method for chemical mechanical polishing of the present invention is useful for polishing a substrate containing copper, particularly semiconductor wafers comprising copper interconnects. The chemical mechanical polishing composition used in the method of the present invention desirably provides a high copper removal rate (>1100 Å) with improved defectivity performance (≦200 defects of >0.1 μm) in a non-selective formulation.

The method for chemical mechanical polishing of a substrate of the present invention is useful for chemical mechanical polishing of a substrate comprising copper. The method for chemical mechanical polishing of a substrate of the present invention is particularly useful for chemical mechanical polishing of a semiconductor wafer having copper interconnects.

The substrate polished using the method of the present invention optionally further comprise an additional material selected from phosphor silicate glass (PSG), boro-phosphor silicate glass (BPSG), undoped silicate glass (USG), spin-on-glass (SOG), tetraethyl orthosilicate (TEOS), plasma-enhanced TEOS (PETEOS), flowable oxide (FOx), high-density plasma chemical vapor deposition (HDP-CVD) oxide, and tantalum nitride (TaN). Preferably, the substrate polished using the method of the present invention further comprises an additional material selected from TaN and TEOS.

Preferably, the water used as an initial component in the chemical mechanical polishing composition used in the method for chemical mechanical polishing of the present invention is at least one of deionized and distilled to limit incidental impurities.

Abrasives suitable for use in the chemical mechanical polishing composition used in the method for chemical mechanical polishing of the present invention include, for example, inorganic oxides, inorganic hydroxides, inorganic hydroxide oxides, metal borides, metal carbides, metal nitrides, polymer particles and mixtures comprising at least one of the foregoing. Suitable inorganic oxides include, for example, silica (SiO₂), alumina (Al₂O₃), zirconia (ZrO₂), ceria (CeO₂), manganese oxide (MnO₂), titanium oxide (TiO₂) or combinations comprising at least one of the foregoing oxides. Modified forms of these inorganic oxides, such as, organic polymer-coated inorganic oxide particles and inorganic coated particles can also be utilized if desired. Suitable metal carbides, boride and nitrides include, for example, silicon carbide, silicon nitride, silicon carbonitride (SiCN), boron carbide, tungsten carbide, zirconium carbide, aluminum boride, tantalum carbide, titanium carbide, or combinations comprising at least one of the foregoing metal carbides, boride and nitrides. Preferably, the abrasive used is a colloidal silica abrasive. More preferably, the abrasive used is a colloidal silica having an average particle size of 1 to 200 nm (more preferably 1 to 100 nm, most preferably 25 to 75 nm) as determined by well known laser light scattering techniques.

The chemical mechanical polishing composition used in the method for chemical mechanical polishing of the present invention preferably comprises, as an initial component, 0.1 to 20 wt %, more preferably 0.5 to 15 wt %, most preferably 10 to 15 wt % abrasive. Preferably, the abrasive is a colloidal silica abrasive. Most preferably, the chemical mechanical polishing composition of the present invention comprises, as an initial component, 10 to 15 wt % of a colloidal silica abrasive having an average particle size of 25 to 75 nm.

The chemical mechanical polishing composition used in the method for chemical mechanical polishing of the present invention comprises, as an initial component, a complexing agent for copper. It is believed that the complexing agent facilitates the removal of copper from the substrate. Preferably, the chemical mechanical polishing composition used comprises, as an initial component, 0.01 to 15 wt % (more preferably 0.1 to 1 wt %, most preferably 0.1 to 0.5 wt %) complexing agent. Complexing agents include, for example, acetic acid, citric acid, ethyl acetoacetate, glycolic acid, lactic acid, malic acid, oxalic acid, salicylic acid, sodium diethyl dithiocarbamate, succinic acid, tartaric acid, thioglycolic acid, glycine, alanine, aspartic acid, ethylene diamine, trimethyl diamine, malonic acid, gluteric acid, 3-hydroxybutyric acid, propionic acid, phthalic acid, isophthalic acid, 3-hydroxy salicylic acid, 3,5-dihydroxy salicylic acid, gallic acid, gluconic acid, pyrocatechol, pyrogallol, tannic acid, including, salts and mixtures thereof. Preferably, the complexing agent used is selected from acetic acid, citric acid, ethyl acetoacetate, glycolic acid, lactic acid, malic acid, oxalic acid and combinations thereof. Most preferably, the complexing agent used is citric acid.

The chemical mechanical polishing composition used in the method for chemical mechanical polishing of the present invention comprises, as an initial component, an inhibitor. It is believed that the inhibitor operates to protect the copper on the surface of the substrate from static etch. Preferably the chemical mechanical polishing composition used comprises, as an initial component, 0.02 to 5 wt % (more preferably 0.05 to 2 wt %, most preferably 0.05 to 1 wt %) inhibitor. The inhibitor used optionally comprises a mixture of inhibitors. The inhibitor used is preferably an azole inhibitor. More preferably, the inhibitor used is an azole inhibitor selected from benzotriazole (BTA), mercaptobenzothiazole (MBT), tolytriazole and imidazole. Most preferably, the inhibitor used is BTA.

The chemical mechanical polishing composition used in the method for chemical mechanical polishing of the present invention comprises, as an initial component, a phosphorus-containing compound. It is believed that the phosphorus-containing compound promotes an accelerated copper removal rate. Preferably, the chemical mechanical polishing composition used comprises 0.01 to 5 wt % (more preferably 0.05 to 3 wt %; still more preferably 0.05 to 0.5 wt %; most preferably 0.05 to 0.2 wt %) phosphorus-containing compound. The term “phosphorus-containing compound” as used herein and in the appended claims means any compound containing a phosphorus atom. Preferably, the phosphorus-containing compound used is selected from phosphates, pyrophosphates, polyphosphates, phosphonates, phosphine oxides, phosphine sulphides, phosphorinanes, phosphonates, phosphites and phosphinates; including, their acids, salts, mixed acid salts, esters, partial esters, mixed esters, and mixtures thereof, such as, phosphoric acid. More preferably, the phosphorus-containing compound used is selected from zinc phosphate, zinc pyrophosphate, zinc polyphosphate, zinc phosphonate, ammonium phosphate, ammonium pyrophosphate, ammonium polyphosphate, ammonium phosphonate, diammonium phosphate, diammonium pyrophosphate, diammonium polyphosphate, diammonium phosphonate, potassium phosphate, dipotassium phosphate, guanidine phosphate, guanidine pyrophosphate, guanidine polyphosphate, guanidine phosphonate, iron phosphate, iron pyrophosphate, iron polyphosphate, iron phosphonate, cerium phosphate, cerium pyrophosphate, cerium polyphosphate, cerium phosphonate, ethylene-diamine phosphate, piperazine phosphate, piperazine pyrophosphate, piperazine phosphonate, melamine phosphate, dimelamine phosphate, melamine pyrophosphate, melamine polyphosphate, melamine phosphonate, melam phosphate, melam pyrophosphate, melam polyphosphate, melam phosphonate, melem phosphate, melem pyrophosphate, melem polyphosphate, melem phosphonate, dicyanodiamide phosphate, urea phosphate, including, their acids, salts, mixed acid salts, esters, partial esters, mixed esters, and mixtures thereof. Most preferably, the phosphorus-containing compound used is selected from at least one of potassium phosphate (e.g., tripotassium phosphate, dipotassium hydrogen phosphate, potassium dihydrogen phosphate and mixtures thereof); ammonium phosphate (e.g., triammonium phosphate, diammonium hydrogen phosphate, ammonium dihydrogen phosphate and mixtures thereof) and phosphoric acid. Excessive ammonium phosphate can introduce undesirable amounts of free ammonium in solution. Excessive free ammonium can attack the copper to produce a rough metal surface. Adding phosphoric acid reacts with free alkali metals in situ, such as potassium to form potassium phosphate salt and dipotassium phosphate salt that are particularly effective.

The chemical mechanical polishing composition used in the method for chemical mechanical polishing of the present invention comprises, as an initial component, polyvinyl pyrrolidone. Preferably, the chemical mechanical polishing composition used comprises, as an initial component, 0.001 to 3 wt % (more preferably 0.05 to 1.5 wt %, most preferably 0.1 to 1 wt %) polyvinyl pyrrolidone.

The polyvinyl pyrrolidone used preferably has a weight average molecular weight of 1,000 to 1,000,000. For purposes of this specification, weight average molecular weight refers to molecular weight measured by gel permeation chromatography. The slurry more preferably has a weight average molecular weight of 1,000 to 500,000 and most preferably a weight average molecular weight of 2,500 to 50,000. For example, polyvinyl pyrrolidone having a weight average molecular weight of 12,000 to 20,000 has proven particularly effective.

Preferably, the chemical mechanical polishing composition used in the method for chemical mechanical polishing of the present invention comprises, as an initial component, guanidine; wherein the guanidine is selected from guanidine, guanidine derivatives, guanidine salts and mixtures thereof. More preferably, the guanidine used is selected from guanidine carbonate and guanidine HCl. Most preferably, the guanidine used is guanidine HCl.

Preferably, the chemical mechanical polishing composition used in the method for chemical mechanical polishing of the present invention comprises, as initial components, >0.1 to 1 wt % (more preferably 0.25 to 1 wt %; most preferably 0.3 to 0.5 wt %) histidine and >0.1 to 1 wt % (more preferably 0.25 to 1 wt %; most preferably 0.3 to 0.5 wt %) guanidine, wherein the guanidine is selected from guanidine, guanidine derivatives, guanidine salts and mixtures thereof (more preferably wherein the guanidine is guanidine HCl). More preferably, the chemical mechanical polishing composition used in the method for chemical mechanical polishing of the present invention comprises, as initial components, >0.1 to 1 wt % (more preferably 0.25 to 1 wt %; most preferably 0.3 to 0.5 wt %) histidine and >0.1 to 1 wt % (more preferably 0.25 to 1 wt %; most preferably 0.3 to 0.5 wt %) guanidine, wherein the guanidine is selected from guanidine, guanidine derivatives, guanidine salts and mixtures thereof (more preferably wherein the guanidine is guanidine HCl); and wherein there is ≦10% (more preferably ≦5%; most preferably ≦1%) difference in the mass of histidine and guanidine included as initial components in the chemical mechanical polishing composition.

The chemical mechanical polishing composition used in the method for chemical mechanical polishing of the present invention optionally comprises, as an initial component, an oxidizer. Preferably, the chemical mechanical polishing composition used comprises, as an initial component, 0 to 25 wt % (more preferably 0.1 to 10 wt %; most preferably 0.1 to 5 wt %) oxidizer. Preferably, the oxidizer used is selected from hydrogen peroxide (H₂O₂), monopersulfates, iodates, magnesium perphthalate, peracetic acid and other per-acids, persulfates, bromates, periodates, nitrates, iron salts, cerium salts, Mn(III), Mn(IV) and Mn(VI) salts, silver salts, copper salts, chromium salts, cobalt salts, halogens, hypochlorites and a mixture thereof. Most preferably, the oxidizer used is hydrogen peroxide. When the chemical mechanical polishing composition contains an unstable oxidizing agent such as, hydrogen peroxide, it is preferable to incorporate the oxidizer into the chemical mechanical polishing composition at the point of use.

The chemical mechanical polishing composition used in the method for chemical mechanical polishing of the present invention optionally comprises, as an initial component, a leveling agent. Leveling agents used can include chlorides. A preferred leveling agent is ammonium chloride. Preferably, the chemical mechanical polishing composition of the present invention comprises, as an initial component, 0 to 0.1 wt % (more preferably 0.01 to 0.1 wt %, most preferably 0.01 to 0.05 wt %) ammonium chloride. It is believed that incorporation of ammonium chloride as an initial component in the chemical mechanical polishing composition used can provide an improvement in surface appearance of the substrate being polished and can facilitate copper removal from the substrate by increasing the copper removal rate.

The chemical mechanical polishing composition used in the method for chemical mechanical polishing of the present invention optionally comprises, as an initial component, a biocide. Preferably, the chemical mechanical polishing composition of the present invention comprises, as an initial component, 0 to 0.01 wt % (more preferably 0.001 to 0.01 wt %) of a biocide. Preferably, the chemical mechanical polishing composition used comprises, as an initial component, a biocide such as an isothiazolinone derivative. Preferred isothiazolinone derivatives include, for example, methyl-4-isothiazolin-3-one; and 5-cloro-2-methyl-4-isothiazolin-3-one (e.g., Kordek™ MLX containing 9.5 to 9.9 wt % methyl-4-isothiazolin-3-one; and Kathon™ ICP III containing a mixture of methyl-4-isothiazolin-3-one and 5-chloro-2-methyl-4-isothiazolin-3-one both commercially available from Rohm and Haas Company).

The chemical mechanical polishing composition used in the method for chemical mechanical polishing of the present invention preferably has a pH of 8 to 12 (more preferably 9 to 11, most preferably 10 to 11). Acids suitable for adjusting the pH of the chemical mechanical polishing composition include, for example, nitric acid, sulfuric acid and hydrochloric acid. Bases suitable for adjusting the pH of the chemical mechanical polishing composition include, for example, ammonium hydroxide, potassium hydroxide, tetramethylammonium hydroxide and bicarbonate; preferably tetramethylammonium hydroxide. Preferably, the chemical mechanical polishing composition of the present invention comprises, as an initial component, 0.1 to 1 wt % potassium hydroxide.

The chemical mechanical polishing composition used in the chemical mechanical polishing method of the present invention optionally further comprises additional additives selected from defoaming agents, dispersants, surfactants and buffers.

The method for chemical mechanical polishing of the present invention preferably comprises: providing a substrate, wherein the substrate comprises copper (preferably, wherein the substrate is a semiconductor substrate with copper interconnects); providing a chemical mechanical polishing slurry composition comprising, as initial components: water; 0.1 to 20 wt % (preferably 0.5 to 15 wt %, more preferably 10 to 15 wt %) of an abrasive (preferably, wherein the abrasive is a colloidal silica abrasive having an average particle size of 25 to 75 nm); 0.01 to 15 wt % (preferably 0.1 to 1 wt %, more preferably 0.01 to 0.5 wt %) of a complexing agent (preferably, wherein the complexing agent is citric acid); 0.02 to 5 wt % (preferably 0.05 to 2 wt %, more preferably 0.05 to 1 wt %) of an inhibitor (preferably, wherein the inhibitor is benzotriazole; 0.01 to 5 wt % (preferably 0.05 to 3 wt %, more preferably 0.05 to 0.5 wt %, most preferably 0.05 to 0.2 wt %) of a phosphorus containing compound (preferably, wherein the phosphorus containing compound is phosphoric acid;
0.001 to 3 wt % (preferably 0.05 to 1.5 wt %, more preferably 0.1 to 1 wt %) of a polyvinyl pyrrolidone (preferably, wherein the polyvinyl pyrrolidone has a weight average molecular weight of 2,500 to 50,000 (more preferably 12,000 to 20,000)); >0.1 to 1 wt % (preferably 0.25 to 1 wt %, more preferably 0.25 to 0.6 wt %) histidine; >0.1 to 1 wt % (preferably 0.25 to 1 wt %, more preferably 0.25 to 0.6 wt %) guanidine, wherein the guanidine is selected from guanidine, guanidine derivatives, guanidine salts and mixtures thereof (preferably, wherein the guanidine is guanidine HCL)(preferably, wherein there is ≦10% (more preferably ≦5%, most preferably ≦1%) difference in the mass of histidine and guanidine HCl included as initial components in the chemical mechanical polishing composition); 0 to 25 wt % (preferably 0.1 to 10 wt %, more preferably 0.1 to 5 wt %) of an optional oxidizing agent (preferably, wherein the oxidizing agent is H₂O₂); 0 to 0.1 wt % (preferably 0.01 to 0.1 wt %, more preferably 0.01 to 0.05 wt %) of an optional leveling agent (preferably, wherein the leveling agent is ammonium chloride); 0 to 0.01 wt % (preferably 0.001 to 0.01 wt %) of an optional biocide; an optional pH adjusting agent (preferably 0.1 to 1 wt % of a pH adjusting agent, wherein the pH adjusting agent is potassium hydroxide); wherein the chemical mechanical polishing slurry composition provided has a pH of 9 to 11 (preferably 10 to 11); providing a chemical mechanical polishing pad with a polishing surface; dispensing the chemical mechanical polishing slurry composition onto the chemical mechanical polishing pad at or near the interface between the chemical mechanical polishing pad and the substrate; and, creating dynamic contact at an interface between the polishing surface of the chemical mechanical polishing pad and the substrate with a down force of 0.69 to 34.5 kPa; wherein the substrate is polished; and, wherein some of the copper is removed from the substrate (preferably, wherein the chemical mechanical polishing composition exhibits a copper removal rate (as measured under the polishing conditions set forth in the Examples) of ≧1100 Å/min (more preferably ≧1500 Å/min) and wherein the chemical mechanical polishing composition facilitates a post polishing SP1 defect count having a size >0.1 μm (as measured under the polishing conditions set forth in the Examples) of ≦200 (more preferably ≦100)). Preferably, the substrate further comprises TEOS, wherein at least some of the TEOS is removed from the substrate, wherein the chemical mechanical polishing composition exhibits a copper removal rate to TEOS removal rate selectivity (as measured under the polishing conditions set forth in the Examples) of 1:1 to 5:1 (more preferably 1:1 to 3:1). Preferably, the substrate further comprises TaN, wherein at least some of the TaN is removed from the substrate, wherein the chemical mechanical polishing composition exhibits a copper removal rate to TaN removal rate selectivity (as measured under the polishing conditions set forth in the Examples) of 1:1 to 5:1 (more preferably 2:1 to 4:1).

The method for chemical mechanical polishing of the present invention preferably comprises: providing a substrate, wherein the substrate comprises copper (preferably, wherein the substrate is a semiconductor substrate with copper interconnects); providing a chemical mechanical polishing slurry composition comprising, as initial components: water; 10 to 15 wt % of the abrasive, wherein the abrasive is a colloidal silica abrasive having an average particle size of 25 to 75 nm; 0.01 to 0.5 wt % of the complexing agent, wherein the complexing agent is citric acid; 0.05 to 1 wt % of the inhibitor, wherein the inhibitor is benzotriazole; 0.05 to 0.2 wt % of the phosphorus containing compound, wherein the phosphorus containing compound is phosphoric acid; 0.1 to 1 wt % of the polyvinyl pyrrolidone, wherein the polyvinyl pyrrolidone has a weight average molecular weight of 12,000 to 20,000; 0.25 to 0.6 wt % histidine; 0.25 to 0.6 wt % guanidine HCl; 0.1 to 5 wt % of the oxidizing agent, wherein the oxidizing agent is H₂O₂; 0.01 to 0.05 wt % of the leveling agent, wherein the leveling agent is ammonium chloride; 0.001 to 0.01 wt % of the biocide; and, 0.1 to 1 wt % of the pH adjusting agent, wherein the pH adjusting agent is potassium hydroxide; and, wherein there is ≦10% difference in the mass of histidine and guanidine HCl included as initial components in the chemical mechanical polishing composition; providing a chemical mechanical polishing pad with a polishing surface; dispensing the chemical mechanical polishing slurry composition onto the chemical mechanical polishing pad at or near the interface between the chemical mechanical polishing pad and the substrate; and, creating dynamic contact at an interface between the polishing surface of the chemical mechanical polishing pad and the substrate with a down force of 0.69 to 34.5 kPa; wherein the substrate is polished; and, wherein some of the copper is removed from the substrate. Preferably, wherein the chemical mechanical polishing composition facilitates a copper removal rate of ≧1100 Å/min (more preferably ≧1500 Å/min) with a post polish SP1 defect count having a size >0.1 μm of ≦200 (more preferably ≦100) with a platen speed of 93 revolutions per minute, a carrier speed of 87 revolutions per minute, a chemical mechanical polishing composition flow rate of 300 ml/min, and a nominal down force of 11.7 kPa on a 200 mm polishing machine using a chemical mechanical polishing pad that comprises a polyurethane polishing layer containing polymeric hollow core microparticles and a polyurethane impregnated non-woven subpad.

Some embodiments of the present invention will now be described in detail in the following Examples.

### EXAMPLES

### Chemical Mechanical Polishing Compositions

All of the chemical mechanical polishing compositions (CMPC's) tested contained, as initial components: 0.04 wt % ammonium chloride; 0.06 wt % benzotriazole; 0.4 wt % polyvinyl pyrrolidone having a weight average molecular weight of 15,000; 0.3 wt % citric acid; 0.1 wt % phosphoric acid; 0.005 wt % biocide (Kordek™ MLX available from Rohm and Haas Company containing 9.5 to 9.9 wt % methyl-4-isothiazolin-3-one); 0.4 wt % potassium hydroxide; 14 wt % abrasive (Klebosol® II 1501-50 colloidal silica having an average particle size of 50 nm manufactured by AZ Electronic Materials and commercially available from Rohm and Haas Electronic Materials CMP Inc.); and 0.4 wt % hydrogen peroxide. The CMPCs contained the additional initial components (if any) as described in Table 1. The chemical mechanical polishing compositions A-C are comparative formulations, which are not within the scope of the claimed invention.

TABLE 1

| | | guanidine | |
|---|---|---|---|
| | histidine | HCl | |
| CMPC | (wt %) | (wt %) | pH |
| A | 0 | 0 | 10.5 |
| B | 0 | 0 | 10.5 |
| C | 0.1 | 0.1 | 10.5 |
| 1 | 0.3 | 0.3 | 10.5 |
| 2 | 0.5 | 0.5 | 10.5 |

### Polishing Tests

Polishing experiments were performed on copper blanket wafers; TaN blanket wafers and TEOS blanket wafers using the chemical mechanical polishing compositions described in Table 1. The polishing experiments were performed using an Applied Materials, Inc. Mirra® 200 mm polishing machine equipped with an ISRM detector system using an VisionPad™ 3100 (with 1010 groves and an SP2310 sub pad) polyurethane polishing pad (commercially available from Rohm and Haas Electronic Materials CMP Inc.) under a 1.7 psi (11.7 kPa) down force, a chemical mechanical polishing composition flow rate of 300 ml/min, a platen speed of 93 rpm, a carrier speed of 87 rpm and a slurry drop point 4.4″ from the center of the polishing pad. A Kinik® AD3BG-150840 diamond pad conditioner (commercially available from Kinik Company) was used to condition the polishing pad. The copper removal rate data reported in Table 2 was determined using a Jordan Valley JVX-5200T metrology tool. The TEOS and TaN removal rates reported in Table 2 were determined by measuring the film thickness before and after polishing using a KLA-Tencor FX200 metrology tool. The defect count analysis for copper defects >0.1 μm is size was performed using a SP1 metrology tool from KLA-Tencor.

TABLE 2

| | Copper | TEOS | TaN | | | |
|---|---|---|---|---|---|---|
| | removal | removal | removal | Total | Cu/TEOS | Cu/TaN |
| | rate | rate | rate | Copper | Selec- | Selec- |
| CMPC | (Å/min) | (Å/min) | (Å/min) | Defect [symbol] | tivity | tivity |
| A | 677 | 914 | 653 | 611 | 0.74 | 1.04 |
| B | 656 | 979 | 641 | 2937 | 0.67 | 1.02 |
| C | 1033 | 918 | 616 | 1104 | 1.13 | 1.68 |
| 1 | 1530 | 819 | 580 | 207 | 1.87 | 2.64 |
| 2 | 1685 | 770 | 488 | 97 | 2.19 | 3.45 |

[symbol]

Total defects on polished copper blanket wafer having a size ≧0.1 μm.

We claim:

1. A method for chemical mechanical polishing of a substrate, comprising:
providing a substrate, wherein the substrate comprises copper;
providing a chemical mechanical polishing slurry composition comprising, as initial components:
water;
0.1 to 20 wt % of an abrasive;
0.01 to 15 wt % of a complexing agent;
0.02 to 5 wt % of an inhibitor;
0.01 to 5 wt % of a phosphorus containing compound;
0.001 to 3 wt % of a polyvinyl pyrrolidone;
>0.1 to 1 wt % histidine;
>0.1 to 1 wt % guanidine, wherein the guanidine is selected from guanidine, guanidine derivatives, guanidine salts and mixtures thereof;
0 to 25 wt % of an optional oxidizing agent;
0 to 0.1 wt % of an optional leveling agent;
0 to 0.01 wt % of an optional biocide; and,
an optional pH adjusting agent;
wherein the chemical mechanical polishing slurry composition provided has a pH of 9 to 11;
providing a chemical mechanical polishing pad with a polishing surface;
dispensing the chemical mechanical polishing slurry composition onto the chemical mechanical polishing pad at or near the interface between the chemical mechanical polishing pad and the substrate; and,
creating dynamic contact at an interface between the polishing surface of the chemical mechanical polishing pad and the substrate with a down force of 0.69 to 34.5 kPa;
wherein the substrate is polished; and, wherein some of the copper is removed from the substrate.

2. The method of claim 1, wherein the chemical mechanical polishing composition exhibits a copper removal rate of ≧1100 Å/min and wherein the chemical mechanical polishing composition facilitates a post polishing SP1 defect count having a size >0.1 μm of ≦200.

3. The method of 2, wherein the substrate further comprises tetraethylorthosilicate; wherein at least some of the tetraethylorthosilicate is removed from the substrate; and, wherein the chemical mechanical polishing composition exhibits a copper removal rate to tetraethylorthosilicate removal rate selectivity of 1:1 to 5:1.

4. The method of claim 2, wherein the substrate further comprises TaN; wherein at least some of the TaN is removed from the substrate; and, wherein the chemical mechanical polishing composition exhibits a copper removal rate to TaN removal rate selectivity of 1:1 to 5:1.

5. The method of claim 1, wherein the chemical mechanical polishing composition provided comprises, as initial components:
water;
0.5 to 15 wt % of the abrasive, wherein the abrasive is a colloidal silica abrasive having an average particle size of 25 to 75 nm;
0.1 to 1 wt % of the complexing agent, wherein the complexing agent is citric acid;
0.05 to 2 wt % of the inhibitor, wherein the inhibitor is benzotriazole;
0.05 to 3 wt % of the phosphorus containing compound, wherein the phosphorus containing compound is phosphoric acid;
0.05 to 1.5 wt % of the polyvinyl pyrrolidone, wherein the polyvinyl pyrrolidone has a weight average molecular weight of 2,500 to 50,000;
0.25 to 1 wt % histidine;
0.25 to 1 wt % guanidine, wherein the guanidine is selected from guanidine, guanidine derivatives, guanidine salts and mixtures thereof;
0.1 to 10 wt % of the oxidizing agent, wherein the oxidizing agent is H₂O₂;
0.01 to 0.1 wt % of the leveling agent, wherein the leveling agent is ammonium chloride;
0.001 to 0.01 wt % of the biocide; and,
0.1 to 1 wt % of the pH adjusting agent, wherein the pH adjusting agent is potassium hydroxide.

6. The method of claim 5, wherein the chemical mechanical polishing composition facilitates a copper removal rate of ≧1100 Å/min with a post polish SP1 defect count having a size >0.1 μm of ≦200 with a platen speed of 93 revolutions per minute, a carrier speed of 87 revolutions per minute, a chemical mechanical polishing composition flow rate of 300 ml/min, and a nominal down force of 11.7 kPa on a 200 mm polishing machine using a chemical mechanical polishing pad that comprises a polyurethane polishing layer containing polymeric hollow core microparticles and a polyurethane impregnated non-woven subpad.

7. The method of claim 6, wherein the substrate further comprises tetraethylorthosilicate; wherein at least some of the tetraethylorthosilicate is removed from the substrate; and, wherein the chemical mechanical polishing composition exhibits a copper removal rate to tetraethylorthosilicate removal rate selectivity of 1:1 to 5:1 with a platen speed of 93 revolutions per minute, a carrier speed of 87 revolutions per minute, a chemical mechanical polishing composition flow rate of 300 ml/min, and a nominal down force of 11.7 kPa on a 200 mm polishing machine using a chemical mechanical polishing pad that comprises a polyurethane polishing layer containing polymeric hollow core microparticles and a polyurethane impregnated non-woven subpad.

8. The method of claim 6, wherein the substrate further comprises TaN; wherein at least some of the TaN is removed from the substrate; and, wherein the chemical mechanical polishing composition exhibits a copper removal rate to TaN removal rate selectivity of 1:1 to 5:1 with a platen speed of 93 revolutions per minute, a carrier speed of 87 revolutions per minute, a chemical mechanical polishing composition flow rate of 300 ml/min, and a nominal down force of 11.7 kPa on a 200 mm polishing machine using a chemical mechanical polishing pad that comprises a polyurethane polishing layer containing polymeric hollow core microparticles and a polyurethane impregnated non-woven subpad.

9. The method of claim 1, wherein the chemical mechanical polishing composition provided comprises, as initial components:
water;
10 to 15 wt % of the abrasive, wherein the abrasive is a colloidal silica abrasive having an average particle size of 25 to 75 nm;
0.01 to 0.5 wt % of the complexing agent, wherein the complexing agent is citric acid;
0.05 to 1 wt % of the inhibitor, wherein the inhibitor is benzotriazole;
0.05 to 0.2 wt % of the phosphorus containing compound, wherein the phosphorus containing compound is phosphoric acid;
0.1 to 1 wt % of the polyvinyl pyrrolidone, wherein the polyvinyl pyrrolidone has a weight average molecular weight of 12,000 to 20,000;
0.25 to 0.6 wt % histidine;
0.25 to 0.6 wt % guanidine, wherein the guanidine is guanidine HCl;
0.1 to 5 wt % of the oxidizing agent, wherein the oxidizing agent is H₂O₂;
0.01 to 0.05 wt % of the leveling agent, wherein the leveling agent is ammonium chloride;
0.001 to 0.01 wt % of the biocide; and,
0.1 to 1 wt % of the pH adjusting agent, wherein the pH adjusting agent is potassium hydroxide; and,
wherein there is ≦10% difference in the mass of histidine and guanidine HCl included as initial components in the chemical mechanical polishing composition.

10. The method of claim 9, wherein the chemical mechanical polishing composition facilitates a copper removal rate of ≧1100 Å/min with a post polish SP1 defect count having a size >0.1 μm of ≦200 with a platen speed of 93 revolutions per minute, a carrier speed of 87 revolutions per minute, a chemical mechanical polishing composition flow rate of 300 ml/min, and a nominal down force of 11.7 kPa on a 200 mm polishing machine using a chemical mechanical polishing pad that comprises a polyurethane polishing layer containing polymeric hollow core microparticles and a polyurethane impregnated non-woven subpad.
